(19) United States
(12) Patent Application Publication
(10) Pub. No.: US 2025/0367704 A1
(43) Pub. Date: Dec. 4, 2025

(54) ULTRASONIC TRANSDUCER

(71) Applicant: Suncall Corporation, Kyoto-shi, Kyoto (JP)

(72) Inventor: Satoru TAKASUGI, Kyoto-shi, Kyoto (JP)

(21) Appl. No.: 18/687,778

(22) PCT Filed: Sep. 1, 2021
(86) PCT No.: PCT/JP2021/032056

§ 371 Date: Jan. 27, 2025

(51) Int. Cl. B06B 1/06; H10N 30/87; H10N 30/88; H10N 39/00

(52) U.S. Cl. CPC B06B 1/0622; H10N 30/875; H10N 30/88; H10N 39/00

(57) ABSTRACT

An ultrasonic transducer of this invention includes a supporting plate having plural cavity portions and waveguides opened to first and second surfaces, respectively, a flexible resin film fixed to the supporting plate, and plural piezoelectric elements fixed to the flexible resin film so that, in a plan view, their center regions overlap with the corresponding cavity portions and their peripheral regions overlap with the supporting plate, the cavity portion and the waveguide portion being set to have a shape and size set so as to suppress transmittance of the sonic wave, which has the frequency within ±1.5% of the resonance frequency of the piezoelectric element.

### FIELD OF THE INVENTION

The present invention relates to an ultrasonic transducer in which a plurality of piezoelectric elements are arranged in parallel and which can be suitably used as a phased array sensor.

### BACKGROUND ART

An ultrasonic transducer in which a plurality of piezoelectric elements functioning as vibrating bodies are arranged in parallel can be suitably used as a phased array sensor for detecting a shape of an object or detecting a presence or absence of an object over a wide range by controlling phases of sonic waves emitted by the plurality of piezoelectric elements.

In a case where there is a dispersion in the resonance frequency among the plurality of piezoelectric elements, a dispersion in the phases of the vibrations is generated among the piezoelectric elements even if phases of voltages having a predetermined frequency that are applied to the plurality of piezoelectric elements are controlled. The dispersion in the phases of the vibrations makes it difficult to precisely control directivity of the sonic wave respectively emitted by the plurality of piezoelectric elements.

Specifically, in order to stably operate the ultrasonic transducer as the phased array sensor, it is needed to uniformize resonance frequencies of the plurality of piezoelectric elements provided in the ultrasonic transducer. However, uniformizing resonance frequencies of the plurality of piezoelectric elements is extremely difficult due to various reasons caused by a material and a manufacturing process.

In this respect, the applicant of the present application filed a patent application regarding an ultrasonic transducer capable of securing an enough vibrational amplitude of the piezoelectric element even in a case where a frequency (driving frequency) of a driving voltage applied to the piezoelectric element functioning as the vibrating body is set to be lower than the resonance frequency of the piezoelectric element, and the patent application has been patented (see Patent Literature 1 shown below).

The ultrasonic transducer disclosed by the Patent Literature 1 is configured to include a rigid substrate with a plurality of opening, a flexible resin film fixed to a top surface of the substrate so as to cover the plurality of openings and a plurality of piezoelectric elements fixed to a top surface of the flexible resin film so as to overlap with the plurality of opening parts, respectively, in a plan view, and thereby effectively securing an enough vibrational amplitude of the piezoelectric element even in a case where the driving frequency is set to be lower than the resonance frequency of the piezoelectric element.

A detection of a position of an object (a distance to the object and a direction of the object) is performed by applying burst waveform voltages, which are phase-controlled, of a predetermined frequency to the plurality of piezoelectric elements in the ultrasonic transducer so as to make the plurality of piezoelectric elements emit sonic waves toward the object, receiving reflected sonic waves returned reflected by the object, and detecting a time length from an emission of the sonic wave until a reception of the reflected wave (the reception of the reflected wave can be performed by the ultrasonic transducer that has emitted the sonic wave, and can be also performed by another reception exclusive ultrasonic transducer).

Here, in order to improve a controllability of directivity of the sonic wave emitted by the ultrasonic transducer, it is desirable that the ultrasonic transducer emits a sonic wave having only component of the driving frequency. In this regard, there is room of improvement in the ultrasonic transducer disclosed by the Patent Literature 1.

### PRIOR ART DOCUMENT

### Patent Literature

Patent Literature 1: Japanese Patent No. 6776481

### SUMMARY OF THE INVENTION

The present invention has been made in consideration of the conventional technology, and it is an object to provide an ultrasonic transducer capable of realizing a sufficiently high sound pressure of the sonic wave emitted by a piezoelectric element even in a case where a frequency (driving frequency) of a driving voltage applied to the piezoelectric element is set to be lower than the resonance frequency of the piezoelectric element, and also improving a controllability of directivity of the sonic wave emitted by the ultrasonic transducer.

In order to achieve the object, the present invention provides an ultrasonic transducer including a rigid supporting plate having first and second surfaces on one side and the other side in a thickness direction, the supporting plate being provided with a plurality of cavity portions opened to the first surface, and a plurality of waveguides having first end portions on one side that are respectively opened to bottom surfaces of the corresponding cavity portions and that have opening widths smaller than those of the corresponding cavity portions and second end portions on the other side that are opened to the second surface; a flexible resin film that is fixed to the first surface of the supporting plate so as to cover the plurality of cavity portions; and the same number of piezoelectric elements as the cavity portions that are fixed to a first surface of the flexible resin film so that their center regions overlap, in a plan view, with the corresponding cavity portions and their peripheral regions overlap, in a plan view, with the first surface of the supporting plate. The cavity portion and the waveguide portion are configured to have a shape and size set so as to suppress transmittance of the sonic wave, which has the frequency within ±1.5% of the resonance frequency of the piezoelectric element.

The ultrasonic transducer according to the present invention makes it possible to realize a sufficiently high sound pressure of sonic waves emitted by the piezoelectric element even in a case where a frequency (driving frequency) of a driving voltage applied to the piezoelectric element is set to be lower than the resonance frequency of the piezoelectric element, and also improve a controllability of directivity of the sonic wave emitted from the ultrasonic transducer

In one embodiment, the waveguide has an opening width that is constant over the whole region in the thickness direction of the supporting plate.

In another embodiment, the waveguide is configured to have a tubular portion including the first end portion, and a horn portion including the second end portion.

The tubular portion has an opening width that is constant in the thickness direction of the supporting plate. The horn portion is configured to have an opening width that is increased as being close to the second end portion from a proximal end side connected to the tubular portion.

For example, the supporting plate is configured to include a first plate body formed with a plurality of through-holes having opening widths same as those of the plurality of cavity portions, and a second plate body formed with a plurality of through-holes having opening widths same as those of the plurality of waveguides. The first and second plate bodies are fixed to each other in a state of being laminated in the thickness direction.

In a preferable embodiment of any one of the above-explained various configurations, the piezoelectric elements each have a rectangular shape in a plan view having longitudinal and lateral dimensions in a plan view with a maximum value of 3.4 mm or less, a circular shape in a plan view having a diameter of 3.4 mm or less, or an elliptical shape in a plan view having a major axis of 3.4 mm or less, the piezoelectric elements being arranged with an arrangement pitch of 4.0 mm.

In this case, the cavity portion has a shape similar to the shape of the piezoelectric element in a plan view so that an overlapping width in a plan view of the peripheral region of the piezoelectric element and the supporting plate is 0.05 mm over the entire circumference.

Preferably, the first end portion of the waveguide has a circular shape with the diameter of 1.5 mm.

In a preferable embodiment, the ultrasonic transducer according to the present invention may further include a lower sealing plate and a wiring assembly.

The lower sealing plate includes a plurality of piezoelectric-element-directed openings having sizes surrounding the plurality of piezoelectric elements and is thicker than the piezoelectric element. The lower sealing plate is fixed to the flexible resin film so that the plurality of piezoelectric elements are positioned within the plurality of piezoelectric-element-directed openings in a plan view, respectively.

The wiring assembly is fixed to the lower sealing plate.

The wiring assembly includes an insulating base layer, a conductive layer including first and second wirings that are arranged on the base layer and that are electrically connected to a pair of first and second application electrodes, respectively, of the piezoelectric element, and an insulative cover layer that covers the conductive layer/

The base layer is provided with a first wiring/piezoelectric element connection opening for electrically connecting the first wiring to the first electrode of the corresponding piezoelectric element and a second wiring/piezoelectric element connection opening for electrically connecting the second wiring to the second electrode of the corresponding piezoelectric element.

The ultrasonic transducer according to the present invention may further include an upper sealing plate fixed to the lower sealing plate and the wiring assembly via a flexible resin.

The upper sealing plate is provided with opening parts at positions corresponding to the plurality of piezoelectric elements.

The ultrasonic transducer according to the present invention may further include a sound absorbing material fixed to the upper sealing plate so as to cover the plurality of opening parts of the upper sealing plate.

The ultrasonic transducer according to the present invention may further include a reinforcing plate fixed to the sound absorbing material.

### BRIEF DESCRIPTION OF THE DRAWINGS

FIG. 1 is a vertical cross-sectional view of a part of an ultrasonic transducer according to one embodiment of the present invention.

FIGS. 2A and 2B are plan and bottom views, respectively, of a piezoelectric body assembly including a supporting plate, a flexible resin film and a plurality of piezoelectric elements of the ultrasonic transducer.

FIG. 3 is a plan view of the supporting plate.

FIG. 4 is a vertical cross-sectional view of a part of an ultrasonic transducer according to a modified example of the embodiment.

FIG. 5A is a plan view of the piezoelectric element, and FIG. 5B is a cross-sectional view along line V-V in FIG. 5A.

FIG. 6 is a graph showing a result of an analysis (1).

FIG. 7A is a plan view of a model used in an analysis (2), and FIG. 7B is a cross-sectional view taken along the line VII-VII in FIG. 7A.

FIG. 8 is a graph showing results of the analyses (1) and (2).

FIG. 9 is a graph enlarging a part of FIG. 8.

FIG. 10A is a plan view of a model used in an analysis (3), and FIG. 10B is a cross-sectional view taken along the line X-X in FIG. 10A.

FIG. 11 is a graph showing a result of an analysis (4).

FIG. 12 is a graph showing a result of an analysis (5).

FIG. 13A is a plan view of a model used in an analysis (6), and FIG. 13B is a cross-sectional view taken along the line XIII-XIII in FIG. 13A.

FIG. 14 is a graph showing a result of the analysis (6).

FIG. 15 is another graph showing a result of the analysis (6).

FIG. 16 is a graph showing a result of an analysis (7).

FIG. 17 is a graph showing a result of an analysis (8).

FIG. 18 is a graph showing a result of a verification (1).

FIG. 19 is a graph showing a result of a verification (2).

FIG. 20 is a cross-sectional view taken along the line XX-XX in FIG. 1.

### EMBODIMENT FOR CARRYING OUT THE INVENTION

One embodiment of an ultrasonic transducer according to the present invention will be described below with reference to the accompanying drawings.

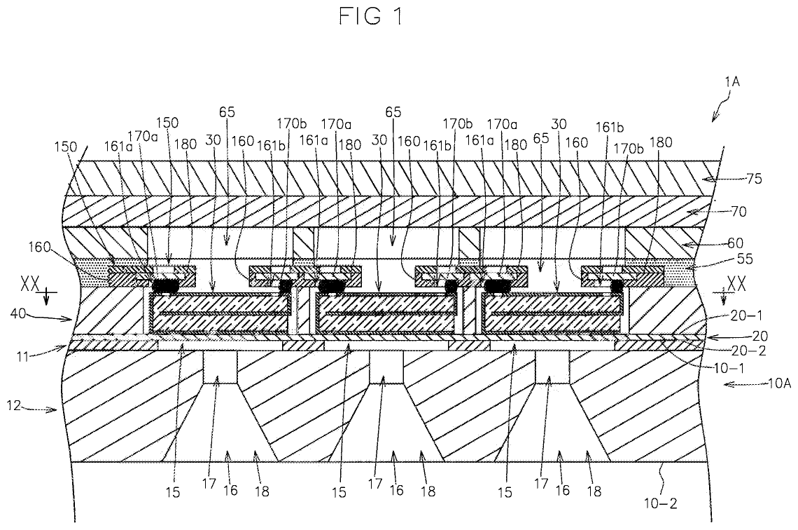

FIG. 1 illustrates a vertically cross-sectional view of a part of an ultrasonic transducer 1 in accordance with the present embodiment.

The ultrasonic transducer 1A includes, as main components, a rigid supporting plate 10A having first and second surfaces 10-1, 10-2 that are positioned on one and the other side in a thickness direction, respectively; a flexible resin film 20 having first and second surfaces 20-1, 20-2 that are positioned on one and the other sides in the thickness direction, respectively, the second surface 20-2 being fixed to the first surface 10-1 of the supporting plate 10A; and a plurality of piezoelectric elements 30 fixed to the first surface 20-1 of the flexible resin film 20.

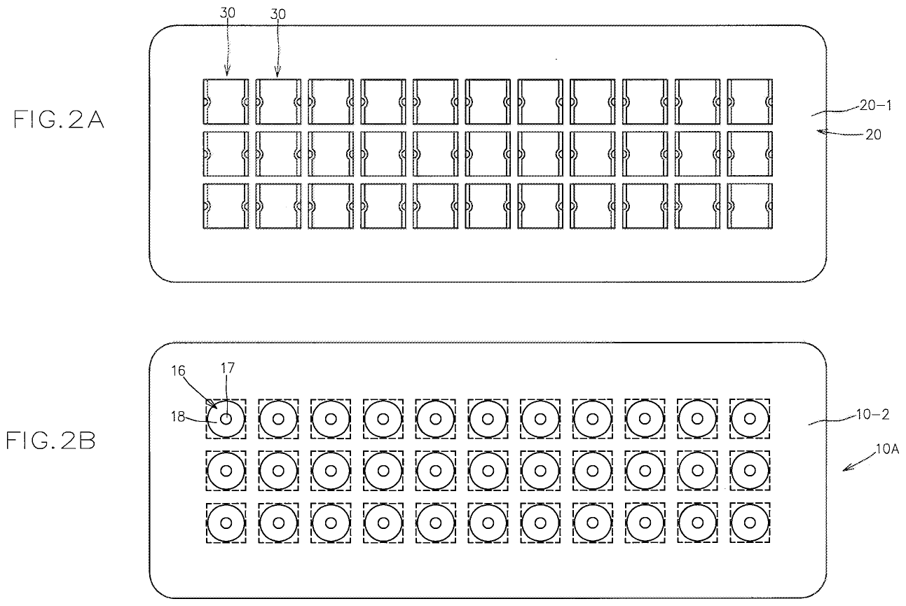

FIG. 2 illustrates a plan view and a bottom view, respectively, of a piezoelectric body assembly including the supporting plate 10A, the flexible resin film 20 fixed to the first surface 10-1 of the supporting plate 10A, and the plurality of (thirty-three in a 3×11 arrangement in the present embodiment) piezoelectric elements 30.

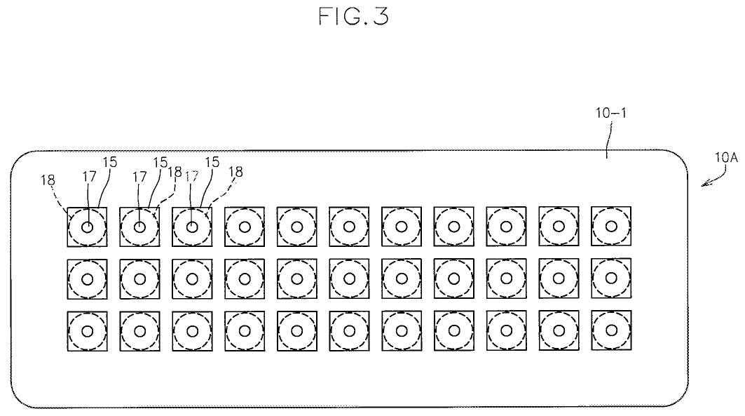

Further, FIG. 3 illustrates a plan view of the supporting plate 10A.

As illustrated in FIGS. 1 to 3, the supporting plate 10 is provided with a plurality of (thirty-three in a 3×11 arrangement) cavity portions 15 opened to the first surface 10-1 of the supporting plate 10A, and a plurality of (thirty-three in a 3×11 arrangement) waveguides 16 having first end portions on one side that are respectively opened to bottom surfaces of the plurality of cavity portions 15 and second end portions on the other side that are opened to the second surface 10-2 of the supporting plate 10A.

The first end portion of the waveguide 16 has an opening width smaller than that of the cavity portion 15.

In the present embodiment, the waveguide 16 includes a tubular portion 17 having the first end portion, and a horn portion 18 having the second end portion.

The tubular portion 17 has an opening width that is constant over the whole region in the thickness direction.

The horn portion 18 is formed to have an opening width that is increased as being close to the second end portion from a proximal end side connected to the tubular portion.

The supporting plate 10A may be formed of various rigid materials including a metal such as stainless steel and, in a preferable embodiment, ceramics such as SiC and Al₂O₃ having density smaller and Young's modulus higher than metal.

Forming the supporting plate 10A from ceramics makes it possible to increase a resonance frequency of the supporting plate 10A as much as possible.

As shown in FIG. 1, in the present embodiment, the supporting plate 10A includes a first plate body 11 formed with a plurality of through-holes having opening widths same as those of the plurality of cavity portions 15, and a second plate body 12 formed with a plurality of through-holes having opening widths same as those of the plurality of waveguides 16, the first and second plate bodies 11, 12 being fixed to each other in a state of being laminated in the thickness direction.

It is possible to utilize a supporting plate 10B formed from a single member in place of the supporting plate 10A including the first and second plate bodies 11, 12.

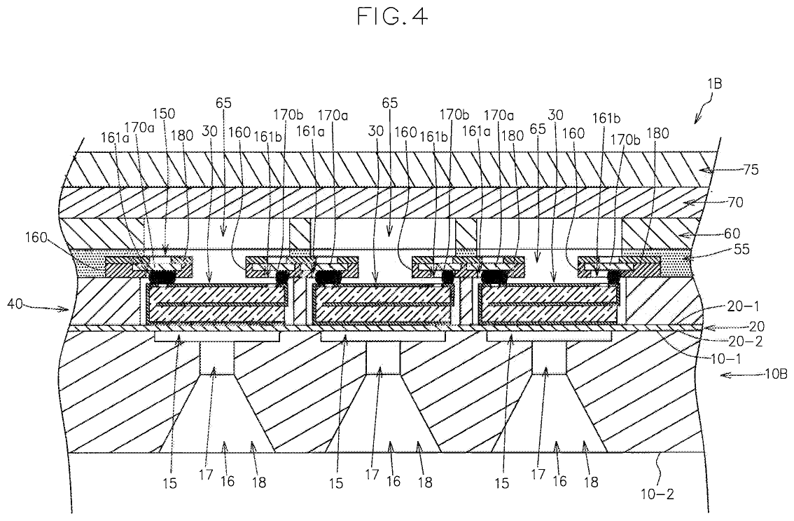

FIG. 4 illustrates a vertically cross-sectional view of a part of an ultrasonic transducer 1B in accordance with a modified example of the present embodiment, the ultrasonic transducer 1B including the supporting plate 10B in place of the supporting plate 10A.

The flexible resin film 20 is fixed to the first surface 10-1 of the supporting plate 10 so as to cover the plurality of cavity portions 15.

The flexible resin film 20 is formed of an insulating resin such as polyimide having a thickness of 20 μm to 100 μm, for example. The flexible resin film 20 is fixed to the supporting plate 10A (10B) by various methods such as an adhesive or thermocompression bonding.

The ultrasonic transducer 1A (1B) includes the same number of (thirty-three in a 3×11 arrangement in the present embodiment) piezoelectric elements 30 as the plurality of cavity portions 15.

The piezoelectric element 30 is fixed to the first surface 20-1 of the flexible resin film 20 in such a manner that a center region of the piezoelectric element 30 overlaps with the corresponding cavity portion 15 and a peripheral region of the piezoelectric element 30 overlaps with the first surface 10-1 of the supporting plate 10 in a plan view.

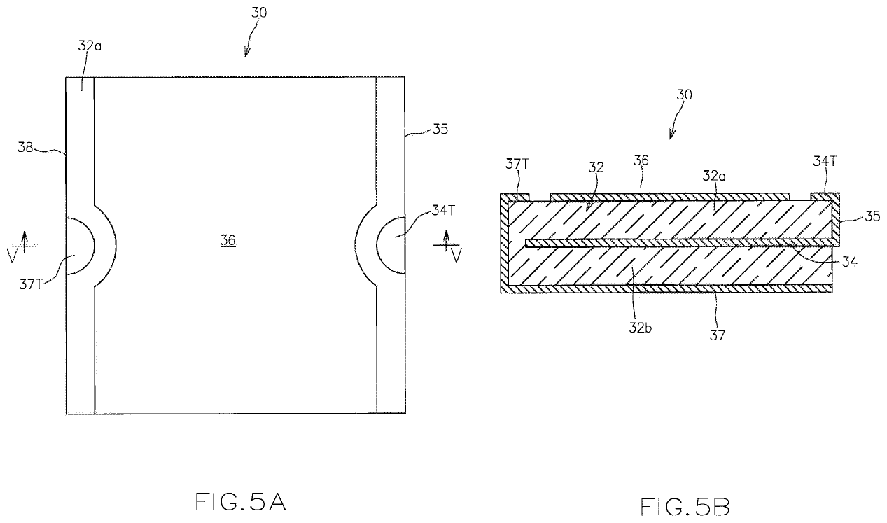

FIG. 5A illustrates a plan view of the piezoelectric element 30.

Further, FIG. 5B illustrates a cross-sectional view taken along line V-V in FIG. 5A.

The piezoelectric element 30 includes a piezoelectric element main body 32 and a pair of first and second application electrodes, and is configured to expand and contract when a voltage is applied between the first and second application electrodes.

As shown in FIGS. 5A and 5B, in the present embodiment, the piezoelectric element 30 is a two-layer laminated type piezoelectric element. With the laminated type piezoelectric element, it is possible to increase the electric field strength when the same voltage is applied and increase the expansion/contraction displacement per applied voltage as compared with a single-layer type piezoelectric element.

Specifically, the piezoelectric element 30 includes the piezoelectric element main body 32 formed of a piezoelectric material such as lead zirconate titanate (PZT), an inner electrode 34 that partitions the piezoelectric element main body 32 into a first piezoelectric portion 32a on an upper side and a second piezoelectric portion 32b on a lower side in a thickness direction, a top surface electrode 36 fixed to a part of a top surface of the first piezoelectric portion 32a, a bottom surface electrode 37 fixed to a bottom surface of the second piezoelectric portion 32b, an inner electrode connection member 35 of which one end part is electrically connected to the inner electrode 34 and the other end part forms an inner electrode terminal 34T accessible at the top surface of the first piezoelectric portion 32a while being insulated from the top surface electrode 36, and a bottom surface electrode connection member 38 of which one end part is electrically connected to the bottom surface electrode 37 and the other end part forms a bottom surface electrode terminal 37T accessible at the top surface of the first piezoelectric portion 32a while being insulated from the top surface electrode 36 and the inner electrode 34.

In this case, an outer electrode formed by the top surface electrode 36 and the bottom surface electrode 37 acts as one of first and second electrodes, and the inner electrode 34 acts as the other one of the first and second electrodes.

In the piezoelectric element 30, the first and second piezoelectric portions 32a and 32b have the same polarization direction in the thickness direction, and thus, when a predetermined voltage is applied between the outer electrode and the inner electrode 34 at a predetermined frequency, electric fields in opposite directions are applied to the first and second piezoelectric portions 32a and 32b.

As described above, the top surface electrode 36 and the bottom surface electrode 37 are insulated from each other. Therefore, when the piezoelectric element 30 is formed, it is possible to apply a voltage between the top surface electrode 36 and the bottom surface electrode 37 so that the polarization directions of the first and second piezoelectric portions 32a and 32b may be the same.

In the ultrasonic transducer 1A (1B), the piezoelectric element 30 forms a vibrating body that generates an ultrasonic wave. The vibrating body is configured to have a resonance frequency in a lowest flexural vibration mode higher than a frequency (driving frequency) of a voltage applied to the piezoelectric element 30.

Specifically, to detect an object several meters ahead by a phased array in which a plurality of piezoelectric elements forming vibrating bodies are arranged in parallel, as in the ultrasonic transducer 1A (1B) according to the present embodiment, it is necessary to precisely control phases of sonic waves emitted from the plurality of piezoelectric elements 30.

For example, in a phased array in which a plurality of piezoelectric elements are arranged in parallel directly on a rigid supporting plate such as stainless steel, it is necessary to expand and contract the piezoelectric element against the rigidity of the rigid supporting plate so that the vibrating bodies that are formed by the piezoelectric elements and the rigid supporting plate make flexural vibrations with a predetermined amplitude, to secure a level of generated sound pressure.

For this purpose, it is necessary to set a frequency (driving frequency) of the voltage applied to the piezoelectric elements to a frequency in the vicinity of a resonance frequency in the flexural vibration mode of the piezoelectric element.

However, a phase of a frequency response in the flexural vibration mode of the piezoelectric element with respect to the voltage applied to the piezoelectric element changes largely in the vicinity of the resonance frequency of the vibrating body.

Therefore, to precisely control the phases of the sonic waves generated by the plurality of piezoelectric elements with the aim of achieving the function of a phased array sensor, it is necessary to suppress as much as possible “dispersion” in the resonance frequency among the plurality of vibrating bodies, which is very difficult.

With respect to this point, the ultrasonic transducer 1A (1B) according to the present embodiment includes, as described above, the rigid supporting plate 10A (10B) provided with the plurality of cavity portions 15 that are opened to the first surface 10-1 and the plurality of waveguides 16 having the first end portions that are opened to the bottom surface of the corresponding cavity portions 15 and the second end portions that are opened to the second surface 10-2, the flexible resin film 20 fixed to the first surface 10-1 of the supporting plate 10A (10B) so as to cover the plurality of cavity portions 15, and the plurality of the piezoelectric elements 30 fixed to the first surface 20-1 of the resin film 20 in such a manner that the center regions of the piezoelectric elements 30 overlap with the corresponding cavity portions 15 and the peripheral regions of the piezoelectric elements 30 overlaps with the first surface 10-1 of the supporting plate 10A (10B) in a plan view.

According to such a configuration, even if a frequency of a driving voltage applied to the piezoelectric element 30 is set to be lower than the resonance frequency in the flexural vibration mode of the piezoelectric element 30, it is possible to sufficiently secure a vibration and an amplitude of the piezoelectric element 30 acting as the vibrating body.

Moreover, when the resonance frequencies of the plurality of vibrating bodies are higher than the driving frequency of the driving voltage applied to the piezoelectric elements 30, even if there is a “dispersion” in the resonance frequencies of the plurality of vibrating bodies, there is no great dispersion in the phases of the frequency response in the flexural vibration mode of the plurality of vibrating bodies.

Therefore, the phases of the sonic waves generated by the plurality of piezoelectric elements 30 acting as the vibrating bodies can be precisely controlled.

Specifically, to detect an object several meters ahead by using the ultrasonic transducer 1A (1B) as a phased array sensor, it is necessary to cause the piezoelectric element 30 to emit a low-frequency ultrasonic wave of 30 kHz-50 kHz or the like.

When the resonance frequency of the piezoelectric element 30 is set to a resonance frequency (for example, 75 kHz) sufficiently higher than the driving frequency (30 kHz-50 kHz) of the voltage applied to the piezoelectric element 30, the sound pressure of the ultrasonic wave generated by the vibrating body can be increased by increasing the longitudinal and lateral dimensions of the piezoelectric element 30 in a plan view.

However, on the other hand, in a case where the plurality of piezoelectric elements 30 are arranged in parallel, as in the ultrasonic transducer 1A (1B) according to the present embodiment, to suppress the generation of grating lobes when the sonic waves emitted from the plurality of piezoelectric elements 30 are scanned in an azimuth angle range of ±90 degree, it is necessary that an arrangement pitch of the plurality of piezoelectric elements 30 is equal to or less than half of a wavelength λ of the ultrasonic waves emitted from the piezoelectric elements 30.

Here, the wavelength λ of the ultrasonic wave having a frequency of 40 kHz is 8.6 mm, and thus, to suppress the generation of grating lobes while setting the frequency of the ultrasonic waves emitted by the piezoelectric elements 30 to 40 kHz, it is necessary that an arrangement pitch P of the plurality of piezoelectric elements 30 is equal to or less than 8.6 mm/2=4.3 mm.

Therefore, it is preferable that the longitudinal and lateral dimensions of the piezoelectric element 30 in a plan view are 3.0 mm or more from the viewpoint of ensuring sound pressure, and 4.0 mm or less from the viewpoint of suppressing the generation of grating lobes.

In the present embodiment, the piezoelectric element 30 is configured to have a square shape in a plan view.

It is noted that, instead of the above-described shape, the piezoelectric element 30 may also have a rectangular shape in a plan view including a straight rectangular shape having longitudinal and lateral dimensions in a plan view with a maximum value of 4.30 mm or less, a circular shape in a plan view having a diameter of 4.0 mm or less, or an elliptical shape in a plan view having a major axis of 4.0 mm or less.

The cavity portion 15 is configured to have a shape similar to the shape of the piezoelectric element 30 in a plan view so that an overlapping width in a plan view of the peripheral region of the piezoelectric element 30 and the supporting plate 10A (10B) is 0.05 mm-0.1 mm over the entire circumference.

Specifically, in a case where the piezoelectric element 30 has a square shape in a plan view having one side of 4.0 mm, the cavity portion 15 may preferably have a square shape in a plan view having one side of about 3.8 mm to 3.9 mm. In a case where the piezoelectric element 30 has a circular shape in a plan view having a diameter of 4.0 mm, the cavity portion 15 may preferably have a circular shape in a plan view having a diameter of about 3.8 mm to 3.9 mm.

By the way, detection of a position of an object (a distance to and a direction of the object) by the ultrasonic transducer acting as a phased array sensor is performed by a following manner. Burst waveform voltages having a predetermined driving frequency are applied to the plurality of piezoelectric elements 30 in a state that the phases of the voltages are controlled so that the piezoelectric elements 30 emit sonic waves in a direction to the object, sonic waves that are reflected by the object and returned are received, and the distance to the object is detected based on a period of time from the emission of the sonic wave until the reception of the reflected sonic wave (the reception of the reflected sonic wave can be done by the ultrasonic transducer that have emitted the sonic wave or another reception exclusive ultrasonic transducer).

Accordingly, in order to improve the directivity of the sonic wave emitted by the ultrasonic transducer, it is desirable that the ultrasonic transducer to which the driving voltage is applied is configured to emits the sonic wave including only a frequency component (the driving frequency) of the driving voltage.

Hereinafter, analyses that the inventor of the present invention performed are explained, the analyses related to the frequency of the sonic wave emitted by the ultrasonic transducer 1A according to the present embodiment.

### Analysis (1)

As explained above, in a case where the ultrasonic transducer is used as an air-coupled ultrasonic transducer, a predetermined-cycle sine burst waveform voltage is typically applied to the plurality of piezoelectric elements.

In the present analysis (1), in a case where a five-cycle sine burst waveform voltage of an amplitude of 10 V and a frequency of 40 kHz is applied to the piezoelectric element 30 in the ultrasonic transducer 1A shown in FIG. 1, a speed response at a center point in a plan view of the piezoelectric element 30 is theoretically calculated in a state of assuming that the piezoelectric element 30 is one freedom degree system having a resonance frequency of 75 kHz and a damping ratio of 0.03.

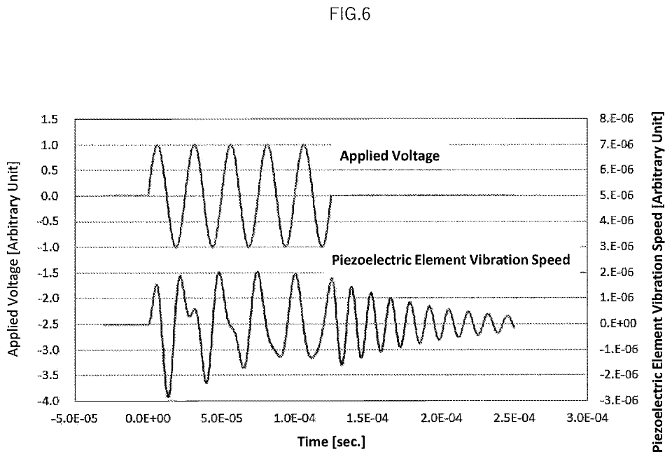

The result is shown in FIG. 6.

It is confirmed from FIG. 6 that a distortion is generated in the speed response of the piezoelectric element 30 with respect to a five-cycle burst waveform voltage having the amplitude of 10 V and the frequency of 40 kHz, and, in addition to that, a damping vibration waveform is generated after the application of the driving voltage is finished.

This phenomenon is considered due to a following reason.

In a case where the voltage (driving voltage) applied to the piezoelectric element 30 has a sine burst waveform of a predetermined frequency, the voltage is suddenly applied at a starting time point of the driving voltage and the applied voltage is suddenly zero at a finishing time point of the driving voltage.

Specifically, at the starting time point and the finishing time point of the sine burst waveform, the waveform of the driving voltage is caused to include frequency components higher than the driving frequency.

Resonance of the piezoelectric element 30 is excited by frequency components close to the resonance frequency of the piezoelectric element 30 among the frequency components higher than the driving frequency.

The excited resonance of the piezoelectric element 30 includes a waveform of damping vibrations starting from the starting time point and the finishing time point of the driving voltage.

A following point is given as a reason. Specifically, the frequency components close to the resonance frequency of the piezoelectric element 30 are included only at the starting time point and the finishing time point of the driving voltage, and the resonance of the piezoelectric element 30 is not excited in time zones other than these time points.

Therefore, as shown in FIG. 6, the speed response of the piezoelectric element 30 has the waveform generated by overlapping the waveform of the damping vibration waveform starting from the starting time point and the finishing time point of the driving voltage with the waveform (the five-cycle burst waveform of the amplitude of 10 V and the frequency of 40 kHz) of the driving frequency.

It is confirmed from the result of the analysis (1) that, in a configuration that includes the supporting plate 10A provided with the plurality of cavity portions 15 and the plurality of waveguides 16, the flexible resin film 20 fixed to the supporting plate 10A so as to cover the plurality of cavity portions 15 and the plurality of the piezoelectric elements 30 fixed to the resin film 20 in such a manner that the center regions of the piezoelectric elements 30 overlap with the corresponding cavity portions 15 and the peripheral regions of the piezoelectric elements 30 overlaps with the first surface 10-1 of the supporting plate 10A in a plan view, as in the ultrasonic transducer 1A according to the present embodiment, the vibration amplitude of the piezoelectric element 30 can be sufficiently secured even if the frequency (the driving frequency) of the driving voltage applied to the piezoelectric element 30 is set to be lower than the resonance frequency in the flexural vibration mode of the piezoelectric element 30, and, on the other hand, the vibration of the piezoelectric element 30 includes the resonance frequency component of the piezoelectric element 30 in addition to the driving frequency component.

Based on the result of the analysis (1), the inventor of the present invention has obtained a new and unique idea that although it is impossible to make the piezoelectric element 30 emit the sonic wave including only the driving frequency component, the directivity of the sonic wave emitted by the ultrasonic transducer 1A may be improved by providing a sonic wave filter, which prevents or reduces transmission of the sonic wave having frequency component close to the resonance frequency of the piezoelectric element 30 while allowing transmission of the sonic wave having frequency component close to the driving frequency, between the piezoelectric element 30 and a sonic wave radiation opening (the second end portion of the waveguide 16) of the ultrasonic transducer 1A, and has performed following analyses regarding the cavity portion 15 and the waveguide 16.

### Analysis (2)

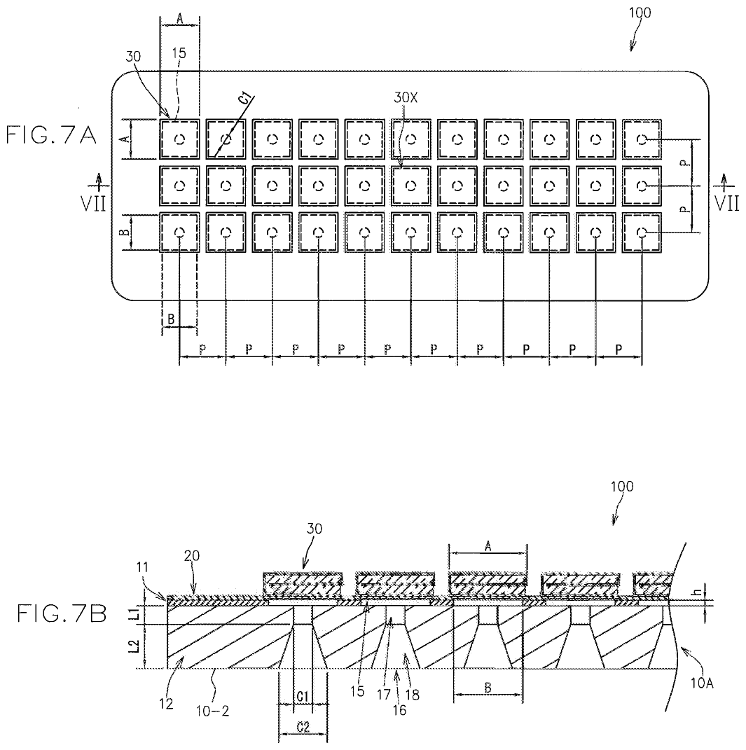

FIG. 7A illustrates a plan view of a model 100 used in this analysis (2).

FIG. 7B illustrates a partial enlarged cross-sectional view taken along the line VII-VII in FIG. 7A.

The model 200 has the supporting plate 10A, the flexible resin film 20 and the thirty-three piezoelectric elements 30 in a 3×11 in the ultrasonic transducer 1A according to the present embodiment.

This analysis (2) is performed as follows. The piezoelectric material of the piezoelectric element 30 was set to have a density of 7.97×10² kg/m³ so that the piezoelectric element 30 has the resonance frequency of 220 kHz. A sine wave voltage having an amplitude of 10 V and frequencies (10-100 kHz) remarkably lower than the resonance frequency was applied to the piezoelectric elements 30 so that the piezoelectric elements 30 emit the corresponding ultrasonic waves. The sound pressure level (hereinafter referred to as SPL) of the radiation sound waves emitted by the piezoelectric elements 30 was calculated by using the finite element method analysis to obtain a SPL frequency characteristic.

The SPL of this analysis (2) is a value at a point on an imaginary vertical line that passes a center in a plan view of a piezoelectric element 30X positioned at a center among the thirty-three piezoelectric elements in a 3×11 arrangement and that is perpendicular to an arrangement plane of the piezoelectric elements 30, the point being away by a distance of 30 cm from the center in a plan view.

In this analysis (2), the finite element method analysis was performed in a condition where all area of the second surface 10-2 of the supporting plate 10A (the second plate body 12) is prevented from being displaced in triaxial directions. This is for eliminating an influence of the vibration of the supporting plate 10A.

A shape and a size of the model 100 were set to be as follows.
Piezoelectric element 30: lead zirconate titanate (PZT)
   3×11 rectangular arrangement pitch P=4.0 mm density 7.97×10² kg/m³ (resonance frequency 220 kHz)
   two-layer laminated type, thickness of one layer 0.13 mm (total thickness of 0.26 mm) square shape in a plan view having one side length of A=3.4 mm
Flexible resin film 20: polyimide film having a thickness of 0.05 mm
First plate body 11: stainless steel having a thickness of h mm
Cavity portion 15: square shape in a plan view having one side length of B=3.3 mm and a depth of h mm
Second plate body 12: alumina (Al₂O₃) having a thickness of 3.0 mm
Tubular portion 17: diameter C1=1.5 mm, length L1=0.25 mm
Horn portion 18: proximal side diameter C1=1.5 mm, emission side diameter C2=3.7 mm, length L2=2.75 mm

The depth h of the cavity portion 15 (the thickness of the first plate body) was set to 0.05 mm (model A1), 0.1 mm (model A2) and 0.2 mm (model A3). The SPLs of the model A1 to A3 were calculated by the finite element method analysis.

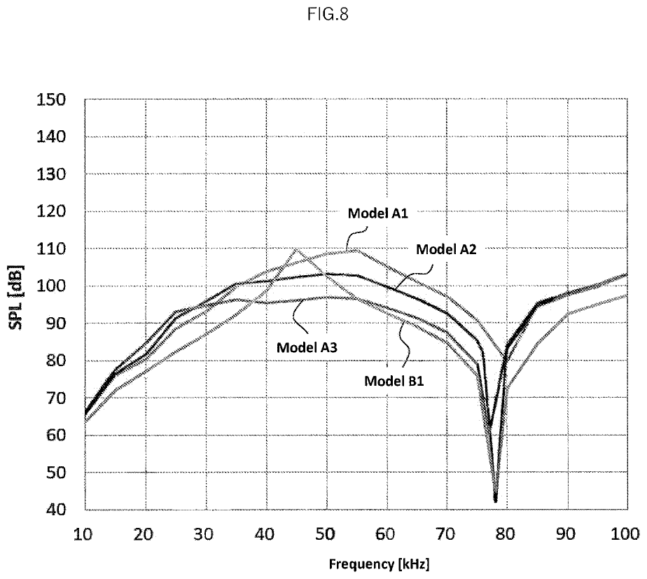

The result is shown in FIG. 8.

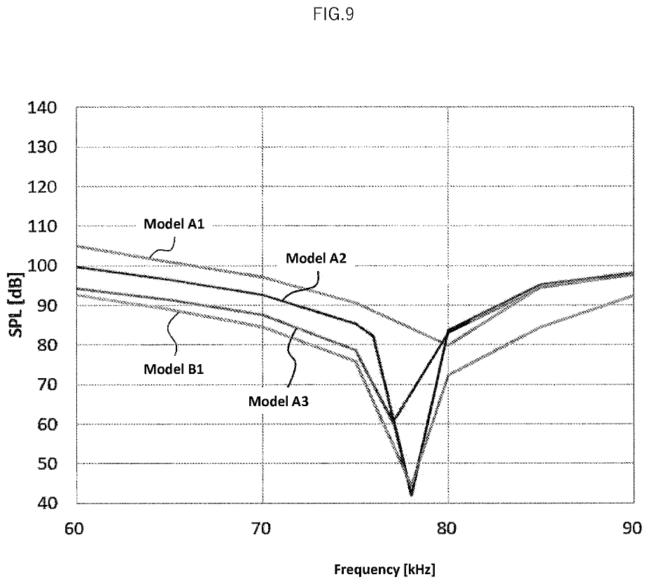

FIG. 9 is an enlarged view of a region where the driving frequency is between 60 and 90 kHz.

As shown in FIGS. 8 and 9, in the models A1 to A3, the SPL is lowered at a region where the driving frequency is 77-88 kHz, and it is confirmed that the sound wave having frequencies in the vicinity of this region is difficult to transmit.

A driving frequency in the model A1 that causes the SPL to be lowered is about 80 kHz, a driving frequency in the model A2 that causes the SPL to be lowered is about 78 kHz, and a driving frequency in the model A2 that causes the SPL to be lowered is about 77 kHz.

It is assumed from these results that a frequency region that causes the SPL to be lowered can be changed by changing the depth h of the cavity portion 15.

### Analysis (3)

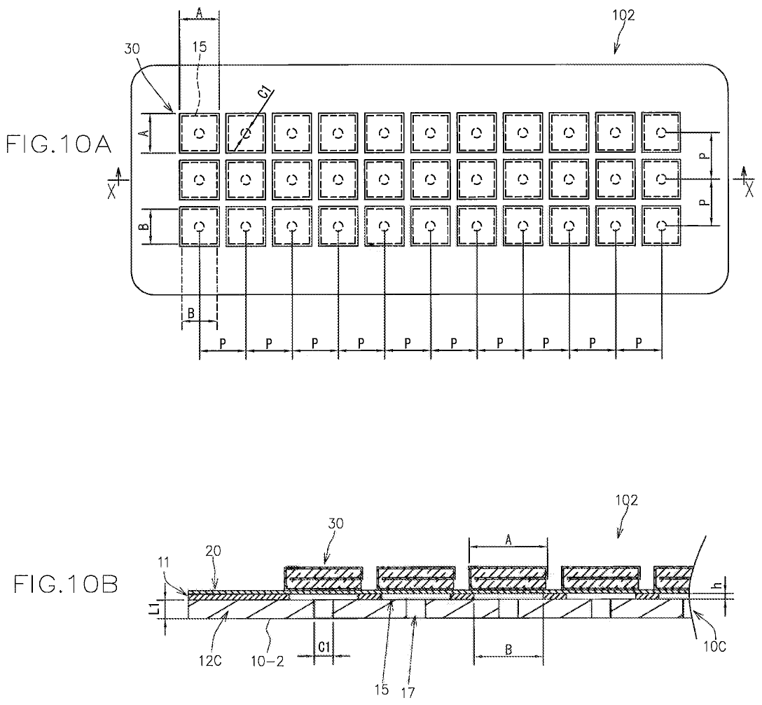

FIG. 10A illustrates a plan view of a model 102 used in this analysis (3).

FIG. 10B illustrates a partial enlarged cross-sectional view taken along the line X-X in FIG. 10A.

The model 102 is different from the model 100 only in that the horn portion 18 is eliminated.

Specifically, the model 102 includes a supporting plate 10C in place of the model 10A in comparison with the model 100.

The supporting plate 10C includes the first plate body 11 and a second plate body 12C.

The second plate body 12C is made of alumina (Al₂O₃) having a thickness of 0.25 mm. A waveguide formed in the second plate body 12C includes only the tubular portion 17 (the diameter C1=1.5 mm and the length L1=0.25 mm).

The SPL of a model (model B1) where the depth h of the cavity portion (the thickness of the first plate body 11) is set to 0.1 mm was calculated by the finite element method analysis.

The result is also shown in FIGS. 8 and 9.

A driving frequency in the model B1 that causes the SPL to be lowered is about 78 kHz, which is same as that in the model A2 of h=0.1 mm.

It is assumed from the result that the presence or absence of the horn portion 18 has no influence to the function that transmission of a sonic wave having a predetermined frequency is prevented or reduced.

### Analysis (4)

In this analysis (4), models B2 to B4 were prepared by setting the diameter C1 of the tubular portion 17 to 1.0 mm (model B2), 1.5 mm (model B3) and 2.2 mm (model B4) in the model 102 (see FIG. 10) where the waveguide includes only the tubular portion 17 while fixing the depth h of the cavity portion 15 (that is, the thickness of the first plate body 11) to 0.1 mm and also fixing the length L1 of the tubular portion 17 (that is, the thickness of the second plate body 12C) to 0.25 mm. The SPLs of the models B2 to B4 were calculated by the finite element method analysis. In the models B2 to B4, other shape and size were set to be same as those of the model B1.

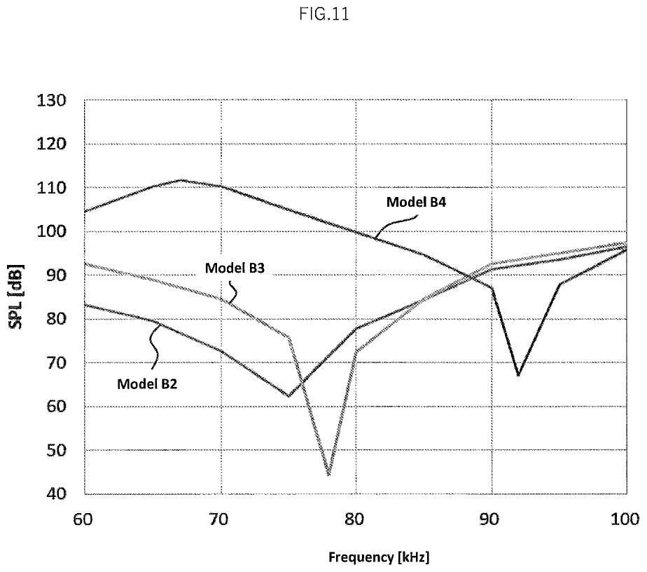

The result of this analysis (4) is shown in FIG. 11.

It is assumed from FIG. 11 that a frequency region that causes the SPL to be lowered can be changed also by changing the diameter of the tubular portion 17.

### Analysis (5)

In this analysis (5), model B5 and model B6 were prepared by setting the length L1 of the tubular portion 17 (that is, the thickness of the second plate body 12C) to 0.25 mm (model B5) and 0.15 mm (model B6) in the model 102 (see FIG. 10) where the waveguide includes only the tubular portion 17 while fixing the depth h of the cavity portion 15 (that is, the thickness of the first plate body 11) to 0.1 mm and also fixing the diameter C1 of the tubular portion 17 to 1.5 mm. The SPLs of the model B5 and the model B6 were calculated by the finite element method analysis.

In the model B5 and the model B6, other shape and size were set to be same as those of the model B1.

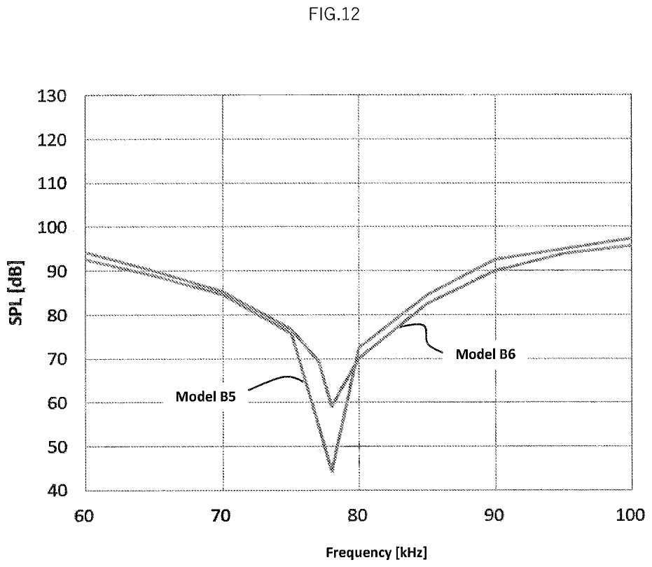

The result of this analysis (5) is shown in FIG. 12.

It is assumed from FIG. 12 that the length L1 of the tubular portion 17 has no influence to the change of the frequency region that causes the SPL to be lowered.

### Analysis (6)

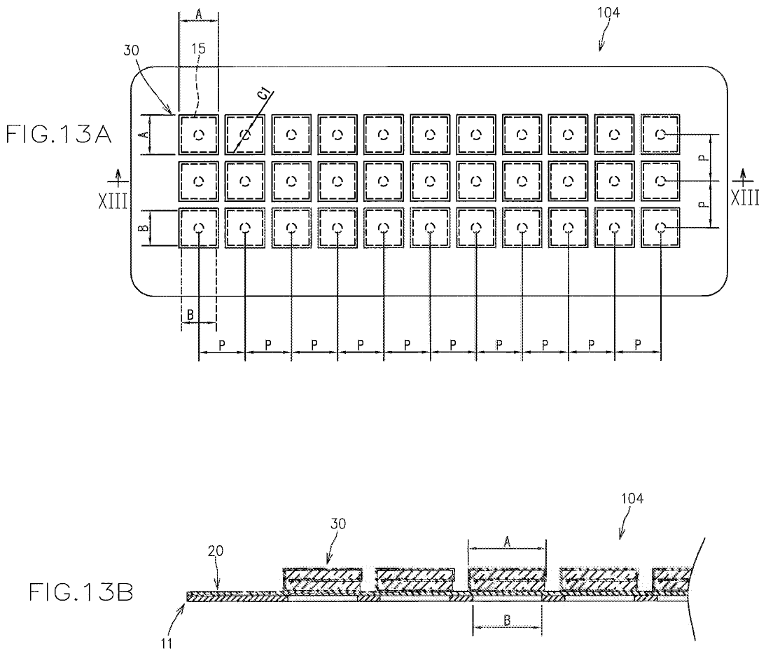

FIG. 13A illustrates a plan view of a model 104 used in this analysis (6)

FIG. 13B illustrates a partial enlarged cross-sectional view taken along the line XIII-XIII in FIG. 13A.

The model 104 is different from the models 100, 102 in that the second plate body 12, 12C is eliminated and the density of the piezoelectric material of the piezoelectric element 30 is set to 9.96×10³ kg/m³ so that the piezoelectric element 30 has the resonance frequency of 75 kHz.

Specifically, the model 104 does not have the cavity portion 15 and the waveguide 16 so that the sonic wave is emitted directly from the piezoelectric element 30.

Model C1 was prepared by setting the thickness of the first plate body 11 to 0.1 mm in the model 104, and the SPL of the model C1 was calculated by the finite element method analysis.

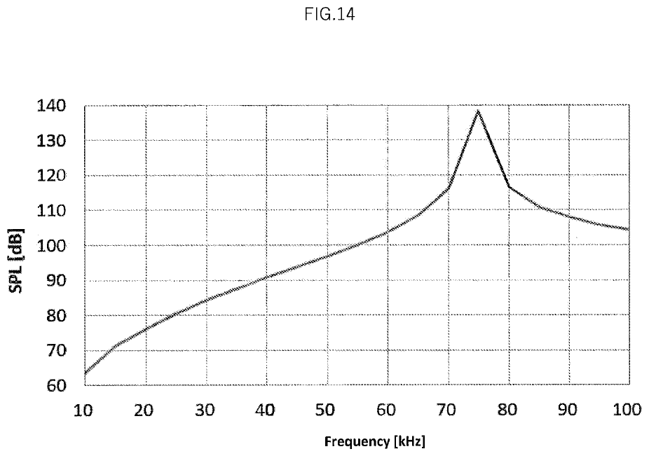

The result is shown in FIG. 14.

The frequency characteristic on the displacement at the center in a plan view of the piezoelectric element 30 in the model C1 was calculated.

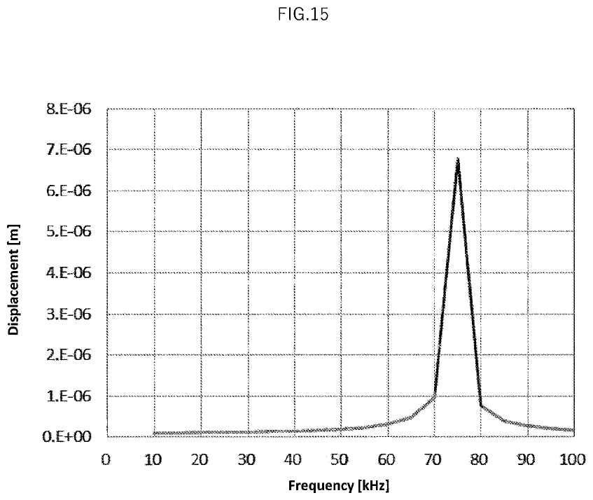

The result is shown in FIG. 15.

As shown in FIGS. 14 and 15, in the model C1 that does not have the cavity portion 15 and the waveguide 16, both of the SPL and the displacement of the piezoelectric element 30 become maximum at about 75 kHz that is the resonance frequency of the piezoelectric element 30, and the frequency characteristic on the displacement of the piezoelectric element 30 appears on the SPL frequency characteristic as it is.

### Analysis (7)

Model A11 to A15 were prepared by setting the resonance frequency of the piezoelectric element 30 to 70 kHz (model A11), 74 kHz (model A12), 75 kHz (model A13), 77 kHz (model A14) and 83 kHz (model A15) in the model 100 (see FIGS. 7A and 7B) having the cavity portion 15 and the waveguide 16 while fixing the depth h of the cavity portion 15 to 0.1 mm. The SPLs of the models A11 to A15 were calculated by the finite element method analysis.

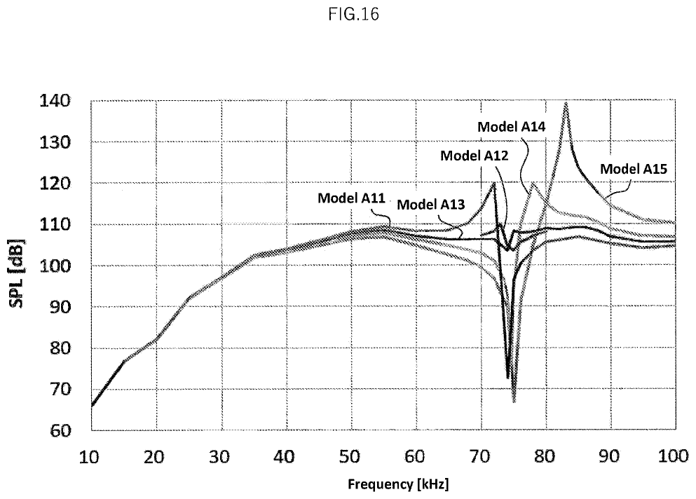

The result is shown in FIG. 16.

Setting the resonance frequencies of the respective models A11 to A15 were performed by changing the density of the piezoelectric material of the piezoelectric element 30.

Specifically, in the models A11 to A15, the density of the piezoelectric material of the piezoelectric element 30 was set as follows.

$$Model A 11 ( resonance frequency 70 kHz ) \text{:} 10.76 \times 1 {0}^{3} kg / {m}^{3}$$

$$Model A 12 ( resonance frequency 74 kHz ) \text{:} 10.12 \times {10}^{3} kg / {m}^{3}$$

$$Model A 13 ( resonance frequency 75 kHz ) \text{:} 9.96 \times 1 {0}^{3} kg / {m}^{3}$$

$$Model A 14 ( resonance frequency 77 kHz ) \text{:} 9.25 \times {10}^{3} kg / {m}^{3}$$

$$Model A 15 ( resonance frequency 83 kHz ) \text{:} 7.97 \times {10}^{3} kg / {m}^{3}$$

As shown in FIG. 16, in the model A11, the SPL is lowered at a region where the driving frequency is about 75 kHz, and the SPL is maximized at a region where the driving frequency is about 72 kHz.

In the model A14, the SPL is lowered at the region where the driving frequency is about 75 kHz, and the SPL is maximized at a region where the driving frequency is about 77 kHz.

In the model A15, the SPL is lowered at the region where the driving frequency is about 75 kHz, and the SPL is maximized at a region where the driving frequency is about 83 kHz.

Followings are assumed from these results.
The cavity portion 15 that has a square shape opening in a plan view having one side whose length B=3.3 mm and also has a depth h of 0.1 mm and the tubular portion 17 that has the diameter C1 of 1.5 mm and the length L1 of 0.25 mm act as the sonic wave filter that prevents or reduces transmission of the sonic wave having frequencies about 75 kHz.
In the model A11 (resonance frequency 70 kHz), the model A14 (resonance frequency 77 kHz) and the model A15 (resonance frequency 83 kHz) where the resonance frequency of the piezoelectric element 30 is different from 75 kHz that is the frequency of the sonic wave prevented or reduced from transmitting by the cavity portion 15 and the tubular portion 17, the emission sonic wave is overlapped with the resonance frequency component.

On the other hand, in the model A13 where the resonance frequency of the piezoelectric element 30 is set to 75 kHz, the SPL is neither lowered nor maximized in the vicinity of frequency 75 kHz.

This is considered because, in the model A13, the component of the resonance frequency 75 kHz of the piezoelectric element 30 that is included in the emitted sonic wave is effectively cut off by the cavity portion 15 and the tubular portion 17 that are configured to prevent or reduce transmittance of the sonic wave having the frequencies about 75 kHz. Also, in the model A12 where the resonance frequency of the piezoelectric element 30 is set to 74 kHz, lowering and maximization of the SPL is considerably suppressed.

This is considered because the component of the resonance frequency 74 kHz of the piezoelectric element 30 that is included in the emitted sonic wave is effectively cut off by the cavity portion 15 and the tubular portion 17 that are configured to prevent or reduce transmittance of the sonic wave having the frequencies about 75 kHz.

From these results, it is considered that the resonance frequency component of the piezoelectric element 30 can be effectively cut off from the emitted sonic wave by forming the cavity portion 15 and the waveguide portion 17 so as to suppress transmittance of the sonic wave having frequencies within ±1.5% of the resonance frequency of the piezoelectric element 30.

As explained in the analyses (2) and (4), adjustment of the frequency of the sonic wave to be prevented or reduced from transmitting can be effectively performed by changing the depth of the cavity portion 15 and/or the diameter of the tubular portion 17 of the waveguide.

### Analysis (8)

Model A21 to A24 were prepared by setting the diameter C1 of the tubular portion 17 to 1.2 mm (model A21), 1.5 mm (model A22), 1.8 mm (model A23) and 2.2 mm (model A24) in the model 100 (see FIGS. 7A and 7B) having the cavity portion 15 and the waveguide 16 while fixing the resonance frequency of the piezoelectric element 30 to 75 kHz and fixing the depth h of the cavity portion 15 to 0.1 mm. The SPLs of the models A21 to A24 were calculated by the finite element method analysis.

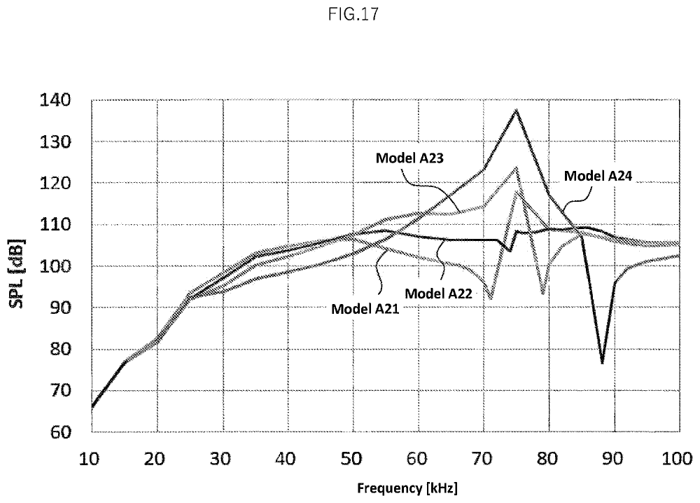

The result is shown in FIG. 17.

As shown in FIG. 17, in the models A21, A23 and A24, the SPL is maximized at a region where the driving frequency is about 75 kHz.

It is assumed because the resonance frequency component of the piezoelectric element 30 is overlapped with the sonic wave emitted from the piezoelectric element 30.

The SPL in the model A21 is lowered when the driving frequency is about 71 kHz, the SPL in the model A23 is lowered when the driving frequency is about 79 kHz, and the SPL in the model A24 is lowered when the driving frequency is about 88 kHz.

It is assumed from these results that the combination of the cavity portion 15 (square shape in a plan view of one side length B=3.3 mm×depth h=1.5 mm) and the tubular portion 17 (diameter C1=1.2 mm×length L1=0.25 mm) in the model A21 suppress transmission of the sonic wave having frequencies about 71 kHz, the combination of the cavity portion 15 (square shape in a plan view of one side length B=3.3 mm×depth h=1.5 mm) and the tubular portion 17 (diameter C1=1.8 mm×length L1=0.25 mm) in the model A23 suppress transmission of the sonic wave having frequencies about 79 kHz, and the combination of the cavity portion 15 (square shape in a plan view of one side length B=3.3 mm×depth h=1.5 mm) and the tubular portion 17 (diameter C1=2.2 mm×length L1=0.25 mm) in the model A23 suppress transmission of the sonic wave having frequencies about 88 kHz.

On the other hand, in the model A22, the SPL is neither lowered nor maximized in a specific frequency region.

This is considered because, although the resonance frequency component of the piezoelectric element 30 is overlapped with the sonic wave emitted from the piezoelectric element 30 when the driving frequency is 75 kHz also in the model A22, the combination of the cavity portion 15 (square shape in a plan view of one side length B=3.3 mm×depth h=1.5 mm) and the tubular portion 17 (diameter C1=1.5 mm×length L1=0.25 mm) in the model A22 suppress transmission of the sonic wave having frequencies about 75 kHz.

Now, verifications that were performed for confirming the effect of the sonic wave filter formed by the cavity portion 15 and the tubular portion 17 are explained.

### Verification (1)

A test product of the same shape, material and size as the model A22 used in the analysis (7) was formed. A voltage (five-cycle sine burst waveform voltage of an amplitude of 10 V) was applied to the test product under the same condition as that in the analysis (1), and a response of the emitted sonic wave was measured in the time domain.

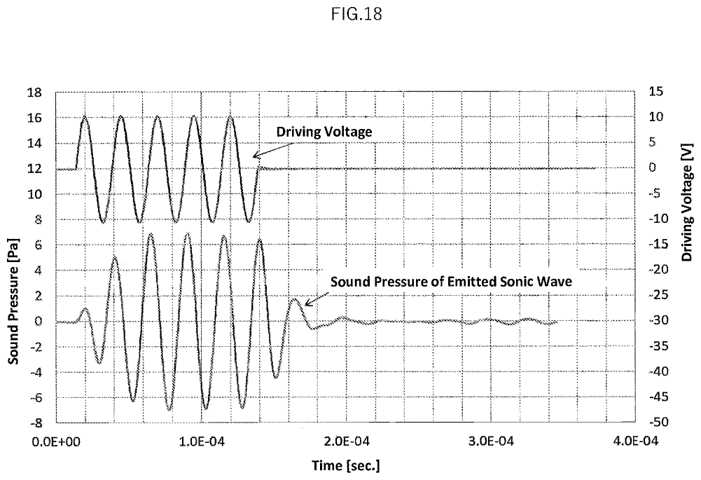

The measured result is shown in FIG. 18.

As shown in FIG. 18, a time-domain waveform of the sound pressure is almost the same as the sine waveform of the driving frequency.

This is considered because, although the sonic wave emitted from the piezoelectric element 30 includes the driving frequency component and, in addition to that, the resonance frequency component of the piezoelectric element 30 that is overlapped therewith, the resonance frequency component of the piezoelectric element 30 is effectively cut off by the sonic wave filter formed by the cavity portion 15 and the tubular portion 17.

### Verification (2)

A directivity of the sound pressure was measured when the driving voltage under the same condition as that in the verification (1) was applied to the test product used in the verification (1).

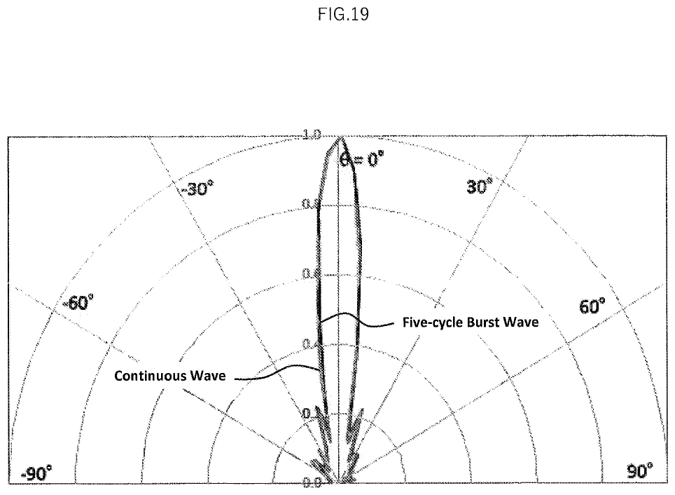

The measured result is shown in FIG. 19.

A directivity of the sound pressure was also measured when a continuous waveform driving voltage (continuous sine waveform voltage of an amplitude of 10 V and a frequency of 40 kHz) was applied to the test product.

The measured result is also shown in FIG. 19.

As shown in FIG. 19, in both cases where the driving voltage is the burst waveform voltage and the continuous waveform voltage, it was confirmed that the directivity is sharp and excellent.

Also, it can be confirmed that the directivity when the burst waveform voltage was applied is almost same shape as the directivity when the continuous waveform voltage is applied.

It is considered because the sonic wave filter formed by the cavity portion 15 and the tubular portion 17 effectively cut off the resonance frequency component of the piezoelectric element 30 from the emitted sonic wave.

Hereinafter, optional components of the ultrasonic transducer 1A will be explained.

As shown in FIG. 1, the ultrasonic transducer 1A according to the present embodiment includes a lower sealing plate 40 and a wiring assembly 150 as the optional components, in addition to the supporting plate 10A, the flexible resin film 20 and the plurality of piezoelectric elements 30.

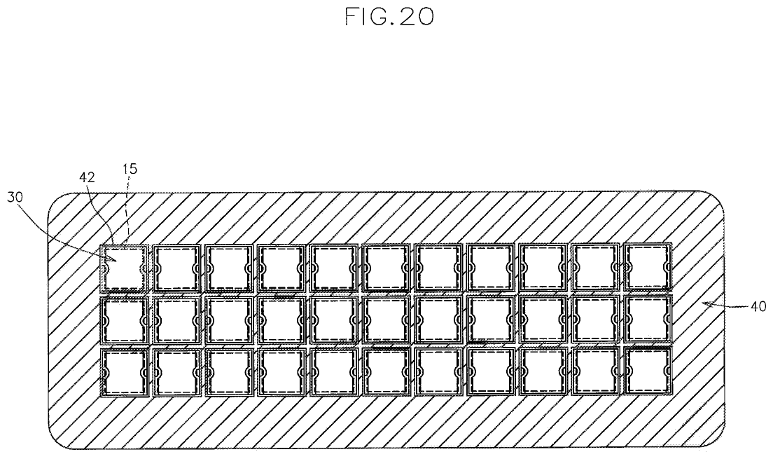

FIG. 20 illustrates a cross-sectional view taken along the line XX-XX in FIG. 1.

As shown in FIG. 20, the lower sealing plate 40 includes a plurality of piezoelectric-element-directed openings 42 having a size surrounding the corresponding piezoelectric element 30. The lower sealing plate 40 is fixed to the first surface 20-1 of the flexible resin film 20 by means of adhesive agent, thermocompression bonding or the like so that the plurality of piezoelectric elements 30 are positioned within the plurality of piezoelectric-element-directed openings 42 in a plan view.

As shown in FIG. 1, the lower sealing plate 40 has a thickness greater than the piezoelectric element 30, so that a first surface of the lower sealing plate 40 is positioned farther away from the flexible resin film 20 than top surface electrode 36, the bottom surface electrode terminal 37T and the inner electrode terminal 34T (see FIG. 5) are in a state where the lower sealing plate 40 is fixed to the first surface 20-1 of the flexible resin film 20.

The lower sealing plate 40 is formed of a rigid material including a metal such as stainless steel, carbon fiber reinforced plastic, ceramics, or the like.

The lower sealing plate 40 seals sides of a piezoelectric element group including the plurality of piezoelectric elements 30, and also acts as a mounting base to which the wiring assembly 150 is fixed.

The wiring assembly 150 is used for transmitting an applied voltage supplied from the outside to the plurality of piezoelectric elements 30.

As illustrated in FIG. 1, the wiring assembly 150 includes an insulating base layer 160 fixed to the lower sealing plate 40 by adhesive agent or the like, a conductor layer 170 fixed to the base layer 160, and an insulating cover layer 180 enclosing the conductor layer 170.

The base layer 160 and the cover layer 180 are formed of an insulating resin such as polyimide, for example.

The conductor layer 170 is formed of a conductive metal such as Cu, for example.

The conductor layer 170 may be formed by laminating a Cu foil that has a thickness of about 12 to 25 μm on the base layer 160 and then removing unnecessary portions from the Cu foil by etching.

An exposed portion of Cu forming the conductor layer 170 may be preferably plated with Ni and Au.

In the present embodiment, the conductor layer 170 includes a first wiring 170a and a second wiring 170b that are respectively connected to a first electrode (the outer electrode 36, 37 in the present embodiment) and a second electrode (the inner electrode 34 in the present embodiment) of the piezoelectric element 30.

The base layer 160 is formed with a first wiring/piezoelectric element connection opening 161a for connecting the first wiring 170a to the corresponding first electrode of the piezoelectric element 30 and a second wiring/piezoelectric element connection opening 161b for connecting the second wiring 170b to the corresponding second electrode of the piezoelectric element 30.

In the present embodiment, as described above, the top surface electrode 36 and the bottom surface electrode 37 act as the first electrode, and the inner electrode 34 acts as the second electrode.

Accordingly, a portion of the first wiring 170a that is exposed through the first wiring/piezoelectric element connection opening 161a is electrically connected to both of a part of the top surface electrode 36 and the bottom surface electrode terminal 37T by a conductive adhesive or solder, for example.

Also, a portion of the second wiring 170b that is exposed through the second wiring/piezoelectric element connection opening 161b is electrically connected to the inner electrode terminal 34T by a conductive adhesive or solder, for example.

The cover layer 180 is formed with a first wiring/outside connection opening and a second wiring/outside connection opening for electrically connecting the first and second wirings 170a, 170b to corresponding outside members, respectively.

As shown in FIG. 1, the ultrasonic transducer 1A according to the present embodiment further includes an upper sealing plate 60 fixed to the top surfaces of the lower sealing plate 40 and the wiring assembly 150 via a flexible resin 55.

The upper sealing plate 60 includes opening parts 65 at positions corresponding to the plurality of piezoelectric elements 30.

With the upper sealing plate 60, it is possible to obtain a stable support structure for the wiring assembly 150 while preventing an influence on a flexural vibration operation of the vibrating body as much as possible. For example, the upper sealing plate 60 is formed of a metal such as stainless steel having a thickness of 0.1 mm to 0.3 mm, carbon fiber reinforced plastic, ceramics, and the like.

The ultrasonic transducer 1A according to the present embodiment further includes a sound absorbing member 70 fixed to the top surface of the upper sealing plate 60 by adhesion or the like to cover the plurality of opening parts 65 of the upper sealing plate 60.

The sound absorbing member 70 is formed of a silicone resin having a thickness of about 0.3 mm to 1.5 mm or another foamed resin, for example.

With the sound absorbing member 70, it is possible to effectively suppress ultrasonic waves generated by the piezoelectric elements 30 from being emitted to a side opposite to the side to which the sonic waves are to be emitted (lower side in FIG. 1).

The ultrasonic transducer 1A further includes a reinforcing plate 75 fixed to the top surface of the sound absorbing member 70 by adhesion or the like.

For example, the reinforcing plate 75 is formed of a metal such as stainless steel having a thickness of about 0.2 mm to 0.5 mm, carbon fiber reinforced plastic, ceramics, and the like.

With the reinforcing plate 75, it is possible to prevent an external force from affecting the supporting plate 10 and the piezoelectric elements 30 as much as possible.

### DESCRIPTION OF THE REFERENCE NUMERALS

1A, 1B ultrasonic transducer
10A, 10B supporting plate
10-1 first surface of supporting plate
10-2 second surface of supporting plate
15 cavity portion
16 waveguide
17 tubular portion
18 horn portion
20 flexible resin film

1. An ultrasonic transducer comprising:
a rigid supporting plate having first and second surfaces on one side and the other side in a thickness direction, respectively, the supporting plate being provided with a plurality of cavity portions opened to the first surface, and a plurality of waveguides having first end portions on one side that are opened to bottom surfaces of the corresponding cavity portions and that have opening widths smaller than those of the corresponding cavity portions and second end portions on the other side that are opened to the second surface;
a flexible resin film that is fixed to the first surface of the supporting plate so as to cover the plurality of cavity portions; and
the same number of piezoelectric elements as the cavity portions that are fixed to a first surface of the flexible resin film so that their center regions overlap with the corresponding cavity portions and their peripheral regions overlap with the first surface of the supporting plate in a plan view,
wherein the cavity portion and the waveguide portion have a shape and size set so as to suppress transmittance of the sonic wave, which has the frequency within ±1.5% of the resonance frequency of the piezoelectric element.

2. The ultrasonic transducer according to of claim 1, wherein the waveguide has an opening width that is constant over the whole region in the thickness direction of the supporting plate.

3. The ultrasonic transducer according to of claim 1,
wherein the waveguide has a tubular portion including the first end portion, and a horn portion including the second end portion,
wherein the tubular portion has an opening width that is constant in the thickness direction of the supporting plate, and
wherein the horn portion is configured to have an opening width that is increased as being close to the second end portion from a proximal end side connected to the tubular portion.

4. The ultrasonic transducer of claim 1,
wherein the supporting plate includes a first plate body formed with a plurality of through-holes having opening widths same as those of the plurality of cavity portions, and a second plate body formed with a plurality of through-holes having opening widths same as those of the plurality of waveguides, and
wherein the first and second plate bodies are fixed to each other in a state of being laminated in the thickness direction.

5. The ultrasonic transducer claim 1,
wherein the piezoelectric elements each have a rectangular shape in a plan view having longitudinal and lateral dimensions in a plan view with a maximum value of 3.4 mm or less, a circular shape in a plan view having a diameter of 3.4 mm or less, or an elliptical shape in a plan view having a major axis of 3.4 mm or less, the piezoelectric elements arranged with an arrangement pitch of 4.0 mm, and
wherein the cavity portion has a shape similar to the shape of the piezoelectric element in a plan view so that an overlapping width in a plan view of the peripheral region of the piezoelectric element and the supporting plate is 0.05 mm over the entire circumference.

6. The ultrasonic transducer of claim 5, wherein the first end portion of the waveguide has a circular shape with the diameter of 1.5 mm.

7. The ultrasonic transducer of claim 1, further comprising:
a lower sealing plate that includes a plurality of piezoelectric-element-directed openings having sizes surrounding the plurality of piezoelectric elements and that is thicker than the piezoelectric element, the lower sealing plate being fixed to the flexible resin film so that the plurality of piezoelectric elements are positioned within the plurality of piezoelectric-element-directed openings in a plan view, respectively; and
a wiring assembly fixed to the lower sealing plate,
wherein the wiring assembly includes an insulating base layer, a conductive layer including first and second wirings that are arranged on the base layer and that are electrically connected to a pair of first and second application electrodes, respectively, of the piezoelectric element, and an insulative cover layer that covers the conductive layer, and
wherein the base layer is provided with a first wiring/piezoelectric element connection opening for electrically connecting the first wiring to the first electrode of the corresponding piezoelectric element and a second wiring/piezoelectric element connection opening for electrically connecting the second wiring to the second electrode of the corresponding piezoelectric element.

8. The ultrasonic transducer of claim 7, further comprising an upper sealing plate fixed to the lower sealing plate and the wiring assembly via a flexible resin,
wherein the upper sealing plate is provided with opening parts at positions corresponding to the plurality of piezoelectric elements.

9. The ultrasonic transducer according to claim 8, further comprising a sound absorbing material fixed to the upper sealing plate so as to cover the plurality of opening parts of the upper sealing plate.

10. The ultrasonic transducer according to claim 9, further comprising a reinforcing plate fixed to the sound absorbing material.
